(19) United States
(12) Patent Application Publication
(10) Pub. No.: US 2011/0215366 A1
(43) Pub. Date: Sep. 8, 2011

(54) Light emitting device

(76) Inventors: Koji Tsukagoshi, Chiba-shi (JP); Hitoshi Kamamori, Chiba-shi (JP); Sadao Oku, Chiba-shi (JP); Hiroyuki Fujita, Chiba-shi (JP); Keiichiro Hayashi, Chiba-shi (JP)

(21) Appl. No.: 12/932,121

(22) Filed: Feb. 17, 2011

(30) Foreign Application Priority Data
Mar. 5, 2010 (JP) 2010-049877

(51) Int. Cl. H01L 33/62

(52) U.S. Cl. 257/99; 257/E33.066

(57) ABSTRACT

A light emitting device (1) includes a glass substrate (4) having a recess (2) in a front surface, and a lead frame (5a). A copper material (7) is embedded so that the copper material (7) passes through the lead frame (5a). A light emitting element (6) is mounted on the copper material (7). The glass substrate (4) and the lead frame (5a) are bonded to each other so that the light emitting element (6) is exposed from the recess of the glass substrate (4). Thus, the copper material is embedded in a pass-through manner directly under a region of the lead frame where the light emitting element is disposed. Therefore, adhesion between the glass substrate and the lead frame is ensured, and heat generated by the light emitting element may be efficiently radiated from the rear surface of the glass substrate.

### BACKGROUND OF THE INVENTION

1. Field of the Invention

The present invention relates to a light emitting device in which a light emitting element is mounted on a package using a glass material.

2. Description of the Related Art

In recent years, an electronic component using a glass package has been put to practical use. A glass material has high airtightness, and hence it is possible to prevent moisture or contaminants from entering from the outside. Further, the glass material has a thermal expansion coefficient which is close to that of a silicon substrate of a semiconductor element. Therefore, high reliability is ensured at a mounting surface or at a bonding surface when the semiconductor element is mounted on the glass material. Still further, the glass material is low in cost, and hence an increase in product cost may be suppressed.

FIG. 6 schematically illustrates a cross-sectional structure of a conventional LED light emitting device 100. A plurality of through-electrodes 52 are formed in a glass substrate 51. Electrode metallizations 53B are formed on the through-electrodes 52. A plurality of LED elements 56A are mounted on the electrode metallizations 53B. Upper surfaces of the LED elements 56A are electrically connected to one of the electrode metallizations 53B through wires 57. Electrode metallizations 53A for external connection are formed on a lower surface of the glass substrate 51. The electrode metallizations 53A are electrically connected to the through-electrodes 52. Therefore, power may be supplied to the LED elements 56A through the electrode metallizations 53A.

An Si substrate 54 formed with an opening 58 is provided on an upper surface of the glass substrate 51 so as to surround the LED elements 56A. The Si substrate 54 is anodically bonded to the front surface of the glass substrate 51. The Si substrate 54 has an inclined inner wall surface. A reflective film 55 is formed on the inner wall surface. Light emitted from the LED elements 56A is reflected on the reflective film 55, and exits as light having directivity in an upward direction. The plurality of LED elements 56A are mounted, and hence a light emission intensity may be increased. Heat generated from the LED elements 56A may be radiated to the outside through the through-electrodes 52 and the electrode metallizations 53A (for example, see Japanese Patent Application Laid-open No. 2007-42781 (reference application 1)).

In the reference application 1, the through-electrodes 52 are formed as follows. That is, an inner wall of each of the through holes formed in the glass substrate 51 is plated with Cu or Ni, and then the through holes are filled with a conductive resin or solder. Further, the electrode metallizations 53A located on the lower surface of the glass substrate 51 are formed as follows. A Ti layer is deposited on the surface of the glass substrate by sputtering or evaporation. A Pt layer or an Ni layer, which becomes a barrier layer for protecting the Ti layer, is deposited on the Ti layer by sputtering or evaporation. Then, an Au layer for preventing surface oxidation is deposited by sputtering or evaporation. The layers are patterned by a photoprocess.

FIG. 7 is an external view of a high-frequency glass terminal package 60. On a base 65 made of a metal material, two side plates 64 opposed to each other and two side walls 66 opposed to each other are provided, to thereby form a package for storing a high frequency semiconductor element. Two glass terminals 63 are provided in each of the two side plates 64, and a lead wire 62 is drawn out from each of the glass terminals 63. The side plates 64, in which the glass terminals 63 are formed, are made of a metal material which has the same thermal expansion coefficient as the glass material. Further, the two side walls 66 and the base 65 are made of a metal having high thermal conductivity. The two side plates 64, the two side walls 66, and the base 65, which constitute the package 60, are bonded to one another by silver solder (for example, see Japanese Patent Application Laid-open No. 1987-212237 (reference application 2)). With this structure, heat generated from the high frequency semiconductor element, which is stored in the package, may be radiated through the side walls 66 and the base 65, which have high thermal conductivity. The side plates 64 have the same thermal expansion coefficient as the glass terminals 63, and hence it is possible to prevent breakage of the glass terminals 63. Further, attachment grooves 61 are formed in the base 65.

However, as in reference application 1, when the conductive resin is filled into the through holes and hardened to form the through-electrodes, shrinkage of the conductive resin occurs during hardening. Therefore, it has been difficult to maintain airtightness. Further, the LED generates heat during light emission. Therefore, when the LED is repeatedly turned ON and OFF, a temperature cycle occurs in which a temperature is repeatedly increased and decreased, and hence expansion and shrinkage are repeated in the LED. As a result, airtightness of an interface between the glass and the through-electrodes reduces, and hence moisture or the like enters from the outside, to thereby shorten the life of the LED.

Moreover, in reference application 2, there is a difference in thermal expansion coefficient between the metal material used in the side plates 64 and the metal material used in the side walls 66 and the base 65. The reason is as follows. The side plates 64 are made of a metal material which has the same thermal expansion coefficient as the glass material which has low thermal conductivity. Therefore, the side plates 64 are inevitably made of a metal material which has low thermal conductivity. Besides, the side walls 66 and the base 65 are made of the metal material having high thermal conductivity and large thermal expansion coefficient. Therefore, in a case where a heat generating element, for example, an LED, is stored in the package 60, large stress is applied to a bonding portion between the side plate 64 and the side wall 66 or a bonding portion between the side plate 64 and the base 65 due to the temperature cycle. Therefore, in the bonding portion, a gap is liable to be formed or peeling is liable to occur, and thus the reliability of the element is reduced.

### SUMMARY OF THE INVENTION

It is an object of the present invention to provide a light emitting device which has high airtightness between an electrode and glass, and also has excellent radiation performance.

A light emitting device according to the present invention includes: a glass substrate having a front surface in which a recess is formed; a lead frame which is bonded to the glass substrate and has a part exposed from a bottom surface of the recess; a light emitting element which is mounted on the part of the lead frame which is exposed from the bottom surface of the recess; and a sealing material which covers the light emitting element. Further, the lead frame has a copper material embedded therein from the bottom surface of the recess to a rear surface of the glass substrate, and the light emitting element is disposed on the copper material. As described above, directly under a region of the lead frame where the light emitting element is mounted, the copper material is embedded in the lead frame so as to pass through the glass substrate. Therefore, adhesion between the glass substrate and the lead frame is ensured, and heat generated from the light emitting element may be efficiently radiated to the rear surface side of the glass substrate.

Further, in a region of the lead frame which is bonded to the glass substrate, an alloy material of Ni and Fe may be provided.

Further, the lead frame may be embedded in the glass substrate, and the lead frame may have one end exposed from the bottom surface of the recess and from the rear surface of the glass substrate, and another end which is protruded from a side surface of the glass substrate. In this case, the lead frame may have a shape in which the lead frame is one of bent and inclined toward the rear surface side of the glass substrate between the side surface of the glass substrate and the bottom surface of the recess.

Further, a light emitting element mounting portion of the lead frame may have a thickness larger than a thickness of another part. In this case, the copper material which is embedded in the lead frame may have a thickness smaller than a thickness of a region of the lead frame around the copper material.

### BRIEF DESCRIPTION OF THE DRAWINGS

In the accompanying drawings:

FIGS. 1A to 1C are explanatory diagrams of a light emitting device according to a first example;

FIG. 2 is a schematic vertical cross-sectional view of a light emitting device according to a second example;

FIG. 3 is a schematic vertical cross-sectional view of a light emitting device according to a third example;

FIG. 4 is a schematic vertical cross-sectional view of a light emitting device according to a fourth example;

FIGS. 5A and 5B are schematic vertical cross-sectional views of a light emitting device according to a fifth example;

FIG. 6 is a cross-sectional view of a conventional known LED light emitting device; and

FIG. 7 is an external view of a conventional known high-frequency glass terminal package.

### DETAILED DESCRIPTION OF THE PREFERRED EMBODIMENT

Hereinafter, an embodiment of a light emitting device is described. The light emitting device includes a glass substrate which has a front surface in which a recess is formed, and lead frames which are bonded to the glass substrate. A protrusion is formed in an outer circumference of the glass substrate, and a region surrounded by the protrusion corresponds to the recess. Parts of the lead frames are exposed from a bottom surface of the recess, and a copper material is embedded in an exposed part of one of the lead frames so as to pass through the corresponding lead frame. A thickness of the glass substrate at a bottom portion of the recess is substantially equal to a thickness of each of the lead frames. That is, the copper material is exposed not only from the bottom surface of the recess of the glass substrate but also from a rear surface thereof. A light emitting element is disposed on the copper material, and is covered with a sealing material.

With this structure, heat generated from the light emitting element is promptly radiated to the rear surface side through the copper material embedded in the lead frame, and hence it is possible to prevent reduction in luminance efficiency due to temperature increase of the light emitting element. Further, adhesion between the glass substrate and the lead frame is excellent, and also airtightness of the copper material is high, and hence it is possible to attain a light emitting device with high reliability.

In addition, a region of the lead frame which is bonded to the glass substrate is made of an alloy of Ni and Fe. With this, bonding and sealing properties between the glass substrate and the lead frame are improved. Further, a difference in thermal expansion between the glass substrate and the lead frame is reduced, and hence it is possible to realize bonding with high reliability, in which a gap is not formed or peeling does not occur with respect to the repeated thermal shock.

In this specification, the copper material collectively refers to a 100% copper and a copper alloy. An example of the copper alloy may include a high thermal conductivity material such as a copper-silver alloy. An NiFe alloy with 20% to 70% of Ni is suitable for the material of the region of the lead frame which is bonded to the glass substrate. In particular, a 42% NiFe alloy or a 45% NiFe alloy, which are alloys of Ni and Fe, or a Kovar containing Ni, Fe, and Co is suitable therefor. Those alloys have a thermal expansion coefficient which approximates that of the glass material, and hence, when the lead frame is bonded to the glass material, sealing property and reliability at a bonding surface therebetween are improved.

Further, the lead frame may be embedded in the glass substrate, and only at a portion on which the light emitting element is mounted, an upper surface of the lead frame may be exposed from the bottom surface of the recess, and a lower surface thereof may be exposed from the rear surface of the glass substrate.

Hereinafter, specific examples of the light emitting device are specifically described with reference to the drawings.

### First Example

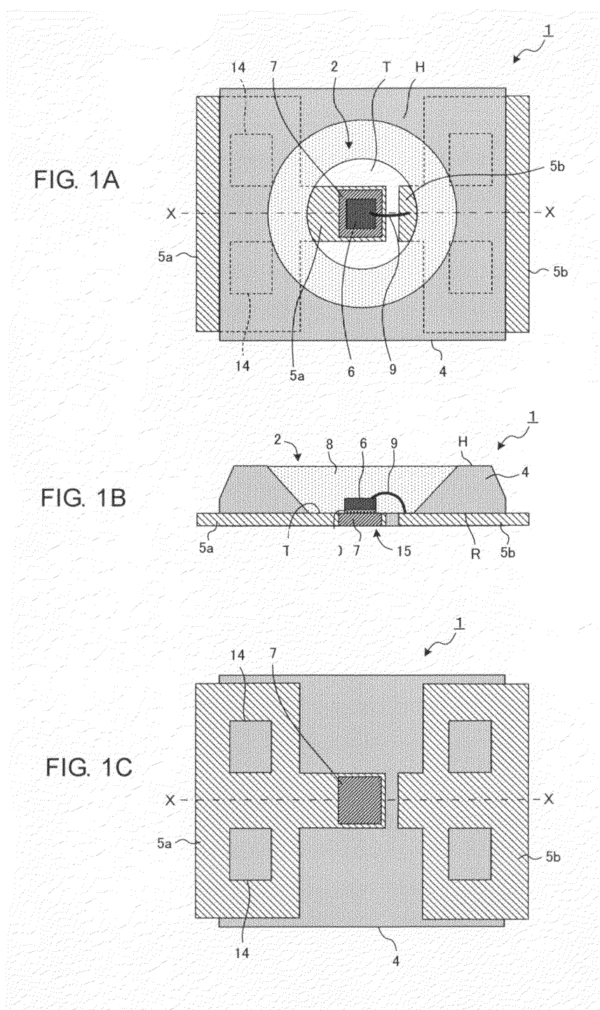

A light emitting device 1 according to a first example is described with reference to FIGS. 1A to 1C. FIG. 1A is a schematic top view of the light emitting device 1, FIG. 1B is a schematic view of a cross section taken along the line XX of FIG. 1A or FIG. 1C, and FIG. 1C is a schematic view seen from the rear side of the light emitting device 1. As is apparent from FIGS. 1A to 1C, a light emitting element 6 is mounted on a copper material 7 which is embedded in a lead frame 5a so as to pass through the lead frame 5a. A glass substrate 4 and the lead frame 5a are bonded to each other so that the light emitting element 6 is exposed from a recess (opening) 2 of the glass substrate 4.

As illustrated in FIGS. 1A to 1C, in the light emitting device 1, the lead frame 5a and a lead frame 5b are bonded to a rear surface R of the glass substrate 4. The recess 2 is formed in a front surface H of the glass substrate 4. The light emitting element 6 is mounted on a part of the lead frame 5a, which is exposed from a bottom surface T of the recess 2, using a bonding material 10. That is, the lead frame 5a is bonded on the rear surface R side of the glass substrate 4 so that the light emitting element 6 is exposed from the opening formed in the glass substrate 4. The copper material 7 which passes through the lead frame 5a is embedded in the lead frame 5a, and the copper material 7 is exposed both on the recess 2 side and on the rear surface R side of the glass substrate 4. The light emitting element 6 is mounted on the recess side of the copper material 7. Two opening portions 14 are formed in each of the lead frames 5a and 5b. In each of the opening portions 14, a glass material of the glass substrate 4 is filled, to thereby form parts of the glass substrate 4 in the opening portions 14 flush with rear surfaces of the lead frames 5a and 5b. The lead frames 5a and 5b are protruded from side surfaces of the glass substrate 4, and the protruded portions are used as electrode terminals. An upper surface of the light emitting element 6 is connected to a part of the lead frame 5b which is exposed from the bottom surface T of the recess 2 through a wire 9. A sealing material 8 is supplied in the recess 2, to thereby cover the light emitting element 6 and the wire 9.

With this structure, power is supplied from the lead frames 5a and 5b to the light emitting element 6, and the light emitting element 6 emits light. Heat generated from the light emitting element 6 is transferred to the copper material 7 embedded in the lead frame 5a, and thus the heat is efficiently radiated to the outside.

The glass substrate 4 and the lead frames 5a and 5b are bonded to each other by fusion, and hence airtightness is maintained with respect to the outside. Here, as the glass substrate 4, a soda-lime glass, a borosilicate glass, or the like may be used. As the lead frames 5a and 5b, an NiFe alloy may be used. The content percentage of Ni in the NiFe alloy is 20% to 70%. For example, as the NiFe alloy, a 42% NiFe alloy, a 45% NiFe alloy, or a Kovar containing cobalt may be used. A thickness of each of the lead frames 5a and 5b is 0.2 mm to 1.0 mm. For example, an NiFe alloy having a thickness of about 0.1 mm to 0.3 mm is used in a region of the lead frame 5a around the copper material 7 which is embedded in a mounting portion 15.

Here, it is preferred that the difference of the thermal expansion coefficient between the glass substrate 4 and the lead frames 5a and 5b be set to a value equal to or lower than 4×10⁻⁶/K. With this, even in a case where the mounted light emitting element 6 is exposed to a thermal cycle due to the repetition of ON/OFF of the light emitting element 6, the bonding between the glass substrate 4 and the lead frames 5a and 5b is maintained, and hence airtightness is held therebetween. Therefore, it is possible to prevent deterioration of the light emitting element 6. Further, the thermal expansion coefficient of the glass substrate 4 is set in a range of from 8×10⁻⁶/K to 11×10⁻⁶/K, and the thermal expansion coefficient of the lead frames 5a and 5b is set in a range of from 4×10⁻⁶ to 15×10⁻⁶/K. With this, a usable material range of the lead frames 5a and 5b may be extended without a significant increase in thermal expansion coefficient difference with the glass substrate 4.

Further, a reflective film such as a multilayer film made of a metal or an insulator may be formed on an inclined surface of the recess 2 to provide a reflective surface function. With this, light emitted from the light emitting element 6 may be efficiently reflected upward. Instead of the formation of the reflective film, a material exhibiting white color or milky white color may be used for the glass substrate 4. For example, the glass material may be mixed with an oxide such as a phosphoric acid (P2O5), an alumina (Al2O3), a calcium oxide (CaO), a boron oxide (B2O3), a magnesium oxide (MgO), a barium oxide (BaO), or a titanium oxide (TiO), to thereby obtain a milky white glass. The white color or the milky white color is not changed by the light emitted from the light emitting element 6 or heat generated in the light emitting element 6, and hence the deterioration of the light emitting device 1 may be prevented.

Further, a transparent resin may be used as the sealing material 8. Instead of the transparent resin, a silicon oxide obtained by curing polymetalloxane may be used. The polymetalloxane is generated from a metal alkoxide. Specifically, a solution containing the metal alkoxide is filled to the recess 2 by a dispenser or the like. For example, a mixture of nSi (OCH₃)₄, 4nH₂O, NH₄OH (catalyst), and dimethylformamide (DMF) (anti-cracking agent) may be used. The mixture is hydrolyzed and polymerized in a temperature range of from room temperature to approximately 60° C. to form a polymetalloxane sol. The mixture is further polymerized in the temperature range of from room temperature to 60° C. to form a wetting gel of a silicon oxide, and then dried and fired at a temperature of approximately 100° C. or a temperature equal to or higher than 100° C. to form the silicon oxide. Alternatively, polymetalloxane may be filled and then polymerized and fired as described above to form the silicon oxide. When the polymetalloxane generated from the metal alkoxide is used as the sealing material 8, the light emitting device 1 may be manufactured using only inorganic materials. Therefore, the materials may be prevented from being discolored by ultraviolet light or visible light emitted from the light emitting element 6.

Further, a metal oxide may be formed on the front surface of the lead frame, to thereby bond the lead frame to the glass substrate 4. The metal oxide may be an oxide of the metal constituting the lead frame. By providing a metal oxide film between the lead frame and the glass substrate, bonding strength and airtightness at bonding portions between the glass substrate 4 and the lead frames 5a and 5b are further improved.

### Second Example

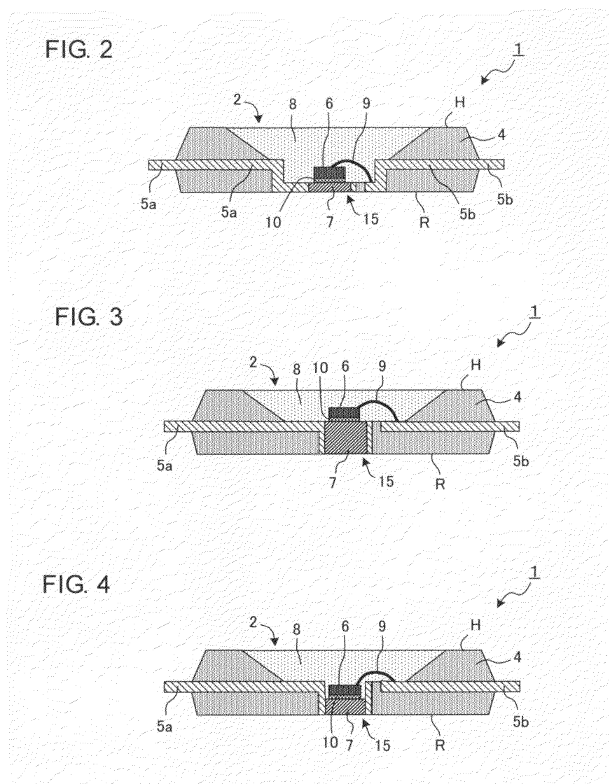

FIG. 2 is a schematic vertical cross-sectional view of a light emitting device 1 according to a second example. The second example differs from the first example in the shape of the lead frames 5a and 5b. Other structures are the same as those in the first example, and hence overlapping description is omitted. In this example, the lead frames 5a and 5b are embedded in the glass substrate 4. As illustrated in FIG. 2, one end of each of the lead frames 5a and 5b is exposed from the bottom surface of the recess 2 and from the rear surface R of the glass substrate 4, and another end thereof is protruded from the side surface of the glass substrate 4 (at a middle portion in height between the front surface H and the rear surface R). The one end of each of the lead frames 5a and 5b is bent toward the rear surface R side of the glass substrate 4 at a bottom portion of the recess 2. The upper surfaces of the lead frames are formed to be flush with the bottom surface of the recess 2, and the lower surfaces thereof are formed to be flush with the rear surface R of the glass substrate 4. Further, the copper material 7 is embedded in the one end of the lead frame 5a at a bending bottom portion, and the light emitting element is mounted on the copper material 7. With this structure, the lead frames 5a and 5b are protruded from the side surfaces of the glass substrate 4 at the middle portions in height of the side surfaces. Further, the copper material 7 which is formed directly under the light emitting element 6, which is a heat generating element, may be formed thin. Therefore, thermal resistance is reduced and radiation performance is improved. Further, a part of each of the lead frames 5a and 5b at a bending upper portion is embedded in the glass substrate 4, and hence it is possible to firmly fix the glass substrate 4 and the lead frames 5a and 5b. Here, the thickness of each of the lead frames 5a and 5b is set to be in a range of from 0.1 mm to 0.5 mm. A NiFe alloy, for example, having a thickness in a range of from 0.1 mm to 0.3 mm is left in a region of the lead frame 5a around the copper material 7 which is embedded in the mounting portion 15.

Note that, in FIG. 2, the lead frames 5a and 5b are bent at the bending portions thereof to a right angle, but alternatively, the lead frames 5a and 5b may be embedded in the glass substrate 4 so as to be inclined from the side surfaces of the glass substrate 4 toward the bottom surface portion of the recess 2. In the case where the lead frames 5a and 5b are inclined, the distance between the bottom surface of the recess and the rear surface of the glass substrate corresponds to the thickness of the each of the lead frames. Even in this case, thermal resistance of the copper material embedded in the lead frame is reduced and radiation performance is further improved.

### Third Example

FIG. 3 is a schematic vertical cross-sectional view of a light emitting device 1 according to a third specific example. The third example differs from the second example in that the mounting portion 15 of the lead frame 5a, on which the light emitting element 6 is mounted, is formed to be thicker than other portions. Other structures are the same as those in the second example, and hence overlapping description is omitted as appropriate. By forming the mounting portion 15 of the lead frame 5a thicker than the other portions, the length of the bonding surface with the copper material embedded in the lead frame or the length of the bonding surface between the lead frame and the glass substrate is increased, and hence airtightness is improved.

As illustrated in FIG. 3, the lead frame 5a has one end including the mounting portion 15 which is exposed on the bottom surface side of the recess 2 and the rear surface R side of the glass substrate 4, and another end protruded from one side surface of the glass substrate 4 (at a middle portion between the front surface H and the rear surface R). The lead frame 5b has one end exposed on the bottom surface side of the recess 2, and another end protruded from another side surface of the glass substrate 4 (at a middle portion between the front surface H and the rear surface R). The copper material 7 passing through the mounting portion is embedded in the mounting portion 15 of the lead frame 5a. That is, the copper material 7 is exposed on the bottom surface side and the rear surface R side of the lead frame 5a. In this case, the copper material 7 is embedded so as not to be in contact with the glass substrate 4.

With this structure, the heat generated from the light emitting element 6 is promptly radiated to the rear surface R side through the copper material 7 having high thermal conductivity. Further, the glass substrate 4 and the copper material 7 are not brought into contact with each other, and the glass substrate 4 is bonded to the lead frame 5a, in which the copper material 7 is embedded, and the lead frame 5b. In this manner, it is possible to attain the light emitting device 1 with high airtightness and reliability.

### Fourth Example

FIG. 4 is a schematic vertical cross-sectional view of a light emitting device 1 according to a fourth example. The fourth example differs from the third example in that the thickness of the copper material 7 is formed thinner. Other structures are the same as those in the third example, and hence overlapping description is omitted as appropriate.

As illustrated in FIG. 4, the copper material 7 is subjected to etching on the side exposed from the bottom surface of the recess 2, to thereby thin the thickness of the copper material 7. Then, the light emitting element 6 is mounted on the upper portion of the etched copper material 7 via the bonding material 10. That is, the copper material 7 embedded in the lead frame is formed to be thinner than the lead frame at the mounting portion. With this, the length of the bonding surface between the glass substrate and the lead frame is ensured, and further the thermal resistance of the copper material 7 may be reduced. Therefore, reliability of bonding and radiation performance are improved.

### Fifth Example

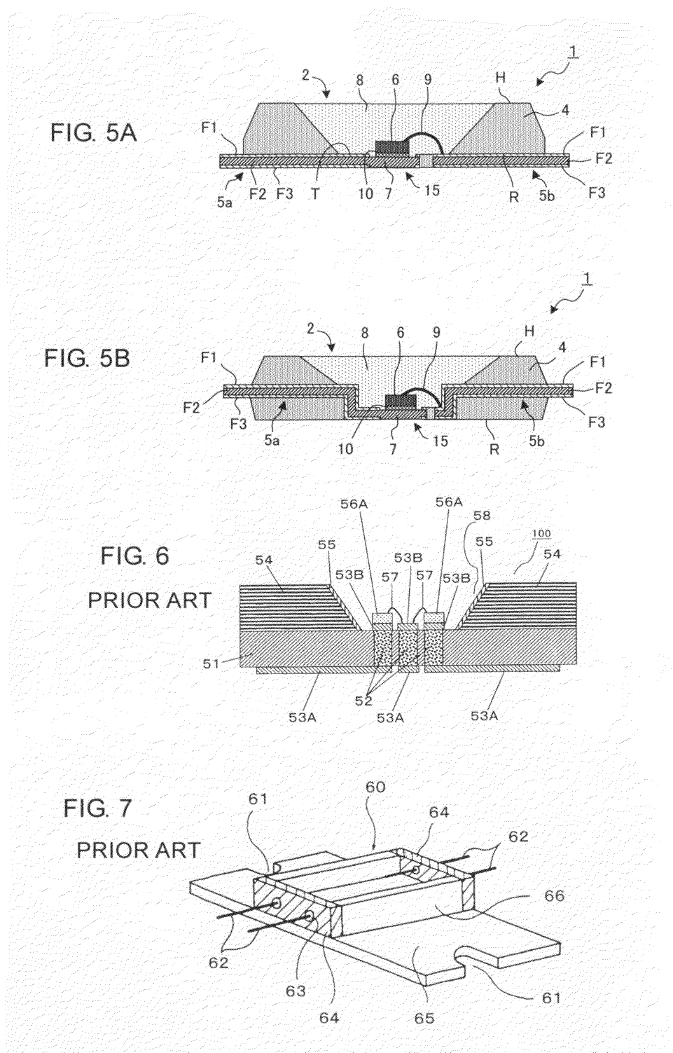

FIGS. 5A and 5B are schematic vertical cross-sectional views of a light emitting device 1 according to a fifth example. Here, a clad material having a three-layer structure is used as each of the lead frames 5a and 5b. FIG. 5A illustrates the light emitting device having a structure corresponding to the first specific example, and FIG. 5B illustrates the light emitting device having a structure corresponding to the second example.

Each of the lead frames 5a and 5b has a three-layer structure including a first layer F1 provided in an upper part, a second layer F2 provided in a middle part, and a third layer F3 provided in a lower part. The first layer F1 and the third layer F3 are formed of, for example, an alloy layer of NiFe, and the second layer F2 provided in the middle part is formed of the copper material 7. With this, the bonding between the glass substrate 4 and the lead frames 5a and 5b and the airtightness are improved, and at the same time, the thermal conductivity is improved. FIG. 5A illustrates an example in which the lead frames 5a and 5b are bonded to the rear surface R of the glass substrate 4, and FIG. 5B illustrates an example in which the lead frames 5a and 5b are embedded in the glass substrate 4, and the lead frames 5a and 5b are bent between the side surfaces of the glass substrate 4 and the bottom surface of the recess 2. In both of the structures, parts of the lead frames 5a and 5b are exposed from the bottom surface of the recess 2 and from the rear surface R of the glass substrate 4 corresponding to the bottom surface.

In both of the structures illustrated in FIGS. 5A and 5B, the first layer F1 of a part of the lead frame 5a, which is exposed from the bottom surface of the recess 2, is removed at the mounting portion 15 on which the light emitting element 6 is mounted, and the copper material 7 corresponding to the second layer F2 is exposed from that portion. Further, the third layer F3 of a part of the lead frame 5a, which is exposed from the rear surface R of the glass substrate 4, is removed at the mounting portion 15, and the copper material 7 corresponding to the second layer F2 is exposed from that portion. The exposed portion on the rear surface R side is formed as follows. After the third layer F3 is subjected to etching, the copper material 7 is deposited by plating, to thereby form the surface of the copper material 7 flush with the outer front surface of the third layer F3. This structure is employed because in a case where heat is transferred by, for example, providing a radiator in contact to the rear surface R side of the glass substrate 4, when a gap corresponding to the thickness of the third layer F3 exists, the thermal resistance is increased.

Note that, in the part of the lead frame 5a which is exposed from the bottom surface of the recess 2, the first layer F1 is removed only at a region on which the light emitting element 6 is mounted, but instead, the first layer F1 may be removed from the entire surface of the part of the lead frame 5a which is exposed from the bottom surface of the recess, to thereby expose the second layer F2. Further, also in the rear surface R side of the glass substrate 4, the third layer F3 may be removed from the entire surface of the exposed part of the lead frame 5a, to thereby expose the second layer F2. The copper material 7 corresponding to the second layer F2 may be exposed by polishing the third layer F3, or the third layer F3 and the rear surface of the glass substrate 4, after the glass substrate 4 and the lead frames 5a and 5b are bonded to each other. Other structures are the same as those in the above-mentioned first to fourth specific examples, and hence description thereof is omitted.

What is claimed is:

1. A light emitting device, comprising:
a glass substrate having a recess in a front surface;
a lead frame bonded to the glass substrate, and having a part exposed from a bottom surface of the recess;
a light emitting element mounted on the part of the lead frame which is exposed from the bottom surface of the recess; and
a sealing material covering the light emitting element, wherein:
the lead frame has a copper material embedded therein from the bottom surface of the recess to a rear surface of the glass substrate; and
the light emitting element is disposed on the copper material.

2. A light emitting device according to claim 1, wherein the lead frame has a region which is bonded to the glass substrate, the region being formed of an alloy material of Ni and Fe.

3. Alight emitting device according to claim 1, wherein:
the lead frame is embedded in the glass substrate; and
the lead frame has one end exposed from the bottom surface of the recess and from the rear surface of the glass substrate, and another end which is protruded from a side surface of the glass substrate.

4. A light emitting device according to claim 3, wherein the lead frame has a shape in which the lead frame is one of bent and inclined toward the rear surface side of the glass substrate between the side surface of the glass substrate and the bottom surface of the recess.

5. A light emitting device according to claim 3, wherein the lead frame has a part on which the light emitting element is mounted, the part having a thickness larger than a thickness of another part.

6. A light emitting device according to claim 5, wherein the copper material has a thickness smaller than a thickness of a region of the lead frame around the copper material.
